(19) United States
(12) Patent Application Publication
(10) Pub. No.: US 2024/0387604 A1
(43) Pub. Date: Nov. 21, 2024

(54) Semiconductor Structures with Compact Copper Conductive Features

(71) Applicant: Taiwan Semiconductor Manufacturing Company, Ltd., Hsin-Chu (TW)

(72) Inventors: Bo-Yu Chiu, Taoyuan City (TW); Yu Ting Yeh, Tainan City (TW); Lu-Ying Lin, Tainan City (TW); Ming-Da Cheng, Taoyuan (TW); Mirng-Ji Lii, Hsinchu County (TW)

(21) Appl. No.: 18/240,843

(22) Filed: Aug. 31, 2023

Related U.S. Application Data
(60) Provisional application No. 63/503,322, filed on May 19, 2023.

(51) Int. Cl. H10N 35/00

(52) U.S. Cl. CPC H01L 28/10; H01L 24/05; H01L 24/13; H01L 24/16; H01L 2224/05611; H01L 2224/05644; H01L 2224/05647; H01L 2224/05655; H01L 2224/05666; H01L 2224/05681; H01L 2224/05686; H01L 2224/13144; H01L 2224/13147; H01L 2224/13155; H01L 2224/16145; H01L 2924/04941; H01L 2924/04953

(57) ABSTRACT

A semiconductor device disclosed herein includes an interconnection structure over a substrate, a first magnetic layer over the interconnection structure, one or more conductive features over the first magnetic layer, a dielectric layer over the first magnetic layer and the one or more conductive features, and a second magnetic layer over the dielectric layer. In some embodiments, the one or more conductive features include a textured top surface.

### PRIORITY DATA

This application claims priority to U.S. Provisional Patent Application Ser. No. 63/503,322 filed May 19, 2023, the entire disclosure of which is hereby incorporated herein by reference.

### BACKGROUND

The electronics industry has experienced an ever-increasing demand for smaller and faster semiconductor devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Many applications implemented on modern semiconductor chips require accurate voltages. Integrated voltage regulators (IVR) may be used to automatically maintain constant voltages. In an IVR device, inductive structures and one or more passivation layers may be formed over a semiconductor substrate including a device layer (e.g., transistors, etc.) and over a multi-layer interconnect (MLI) structure which provides interconnections between various microelectronic components of the substrate and upper contact features. Various contact features and magnetic films can be formed in an IVR device. In various examples, the one or more passivation layers, the MLI structure, the conductive features, and/or the magnetic films may experience stress in certain regions, which may result in delamination, thereby degrading device reliability.

Thus, existing techniques have not proved entirely satisfactory in all respects.

### BRIEF DESCRIPTION OF THE DRAWINGS

Aspects of the present disclosure are best understood from the following detailed description when they are read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a portion of a semiconductor device, in accordance with some embodiments of the present disclosure;

FIG. 2 is a cross-sectional view of a portion of the semiconductor device along the A-A line in FIG. 1, in accordance with some embodiments of the present disclosure; and

FIGS. 3, 4, and 5 are cross-sectional views of portions of packages including the semiconductor device, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

An inductive structure is used in various electronic applications, such as radio frequency filters, alternating current (AC) blockers, voltage regulators, transformers, and/or the like. An inductive structure may include magnetic elements, such as magnetic films. A voltage regulator integrated on-package or on-die may be referred to as an integrated voltage regulator (IVR). IVR devices (such as a coupled inductor voltage regulator (CLVR)) may include an inductive structure and one or more passivation layers formed over a semiconductor substrate including a device layer (e.g., transistors, etc.) and over a multi-layer interconnect (MLI) structure. The MLI structure may include layers of metal lines and metal vias and provides interconnections between various microelectronic components within the semiconductor substrate and upper contact features. The upper contact features, such as contact pads, may be formed in the one or more passivation layers (e.g., for connection to external circuitry). In an IVR device, magnetic films as well as other components (e.g., contact pads, conductive features, dielectric features) may experience stress during the fabrication and/or operation of the IVR device. The magnetic films and/or the other components may not sustain the stress and result in defects (e.g., cracks and/or delamination) of the device, thereby degrading device reliability. In addition, during the operation of the IVR device, excess energy may be wasted. Thus, existing structures have not been entirely satisfactory in all respects.

The present disclosure generally relates to an IVR device, such as a CLVR device. More specifically, the present disclosure proposes a semiconductor device (e.g., an IVR device, a CLVR device) having conductive features that include a compact copper (Cu) material. The disclosed semiconductor device may include an interconnection structure over a substrate. The interconnection structure may include a contact pad over a top metal line. In various examples, the disclosed semiconductor device includes a first magnetic layer over the interconnection structure, two conductors over the first magnetic layer, a dielectric layer over the two conductors, and a second magnetic layer over the dielectric layer. The two conductors and/or the contact pad may include the compact Cu material, which includes greater than 97% of Cu (111). The compact Cu material has a lower modulus and higher conductance as compared to at least some existing implementations, and may have a reduced height of the conductors and/or the conductive pads, thereby reducing stress (e.g., chip package interaction stress, or CPI stress), delamination defects, and/or wasted energy of the semiconductor device. The compact Cu material may also include rough surfaces of the two conductors and/or the contact pad, which also helps in sustaining stress, and mitigating stress and defects (e.g., such as delamination defects). Additional details of embodiments of the present disclosure are provided below, and additional benefits and/or other advantages will become apparent to those skilled in the art having benefit of the present disclosure.

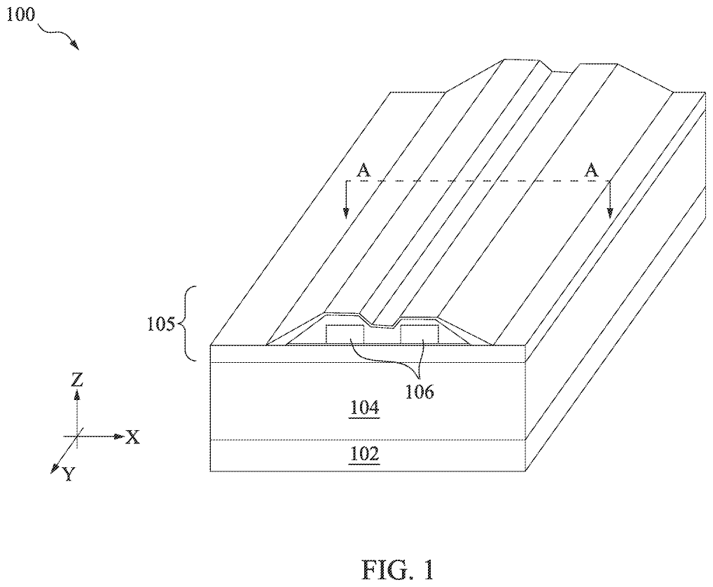

Referring now to FIG. 1, illustrated is a perspective view of a portion of a semiconductor device 100, in accordance with some embodiments. In some embodiments, the semiconductor device 100 includes a substrate 102, an interconnection structure 104 over the substrate 102, and an inductive structure 105 over the interconnection structure 104. In some embodiments, the inductive structure 105 includes one or more conductors 106. The inductive structure 105 and the one or more conductors 106 may extend lengthwise along the Y direction.

The substrate 102 may be a semiconductor substrate such as a silicon substrate. The substrate 102 may include various layers, including conductive or insulating layers formed on the substrate 102. The substrate 102 may include various doping configurations depending on design requirements as is known in the art. The substrate 102 may also include other semiconductors such as germanium, silicon carbide (SiC), silicon germanium (SiGe), or diamond. Alternatively, the substrate 102 may include a compound semiconductor and/or an alloy semiconductor. Further, in some embodiments, the substrate 102 may include an epitaxial layer (epi-layer), the substrate 102 may be strained for performance enhancement, the substrate 102 may include a silicon-on-insulator (SOI) structure, and/or the substrate 102 may have other suitable enhancement features.

In some embodiments, the substrate 102 includes one or more active and/or passive semiconductor devices such as transistors, diodes, optoelectronic devices, resistors, capacitors, sensors, or other devices. In various examples, the transistors may include source/drain features, gate structures, gate spacers, contact features, isolation structures such as shallow trench isolation (STI) structures, or other suitable components. By way of example, the active and/or passive semiconductor devices formed within the substrate 102 may be formed as part of a front-end-of-line (FEOL) process.

In some embodiments, the substrate 102 includes one or more dielectric layers. The one or more dielectric layers may include silicon oxide or a silicon oxide containing material. In some cases, the one or more dielectric layers may include undoped silicate glass (USG). In various examples, the one or more dielectric layers may be deposited by plasma enhanced CVD (PECVD), high-density plasma CVD (HDP-CVD), sub-atmospheric CVD (SACVD), ALD, PVD, or a combination thereof.

In some embodiments, the substrate 102 includes an interlayer dielectric (ILD) layer. The ILD layer may include silicon oxide, a silicon oxide containing material, or a low-k dielectric layer such as TEOS oxide, undoped silicate glass (USG), or doped silicon oxide such as BPSG, FSG, PSG, BSG, and/or other suitable low-k dielectric material. In various examples, the ILD layer may be deposited by chemical vapor deposition (CVD), physical vapor deposition (PVD), atomic layer deposition (ALD), or combinations thereof.

In some embodiments, the substrate 102 includes an etch stop layer (ESL). In some cases, the ESL includes a nitrogen-containing material and/or a carbon-containing material. For example, the ESL may include silicon carbon nitride (SiCN), silicon oxycarbide (SiOC), silicon carbide (SiC), silicon oxycarbonitride (SiOCN), silicon nitride (SiN), or combinations thereof. In various examples, the ESL may be deposited by CVD, ALD, PVD, or combinations thereof.

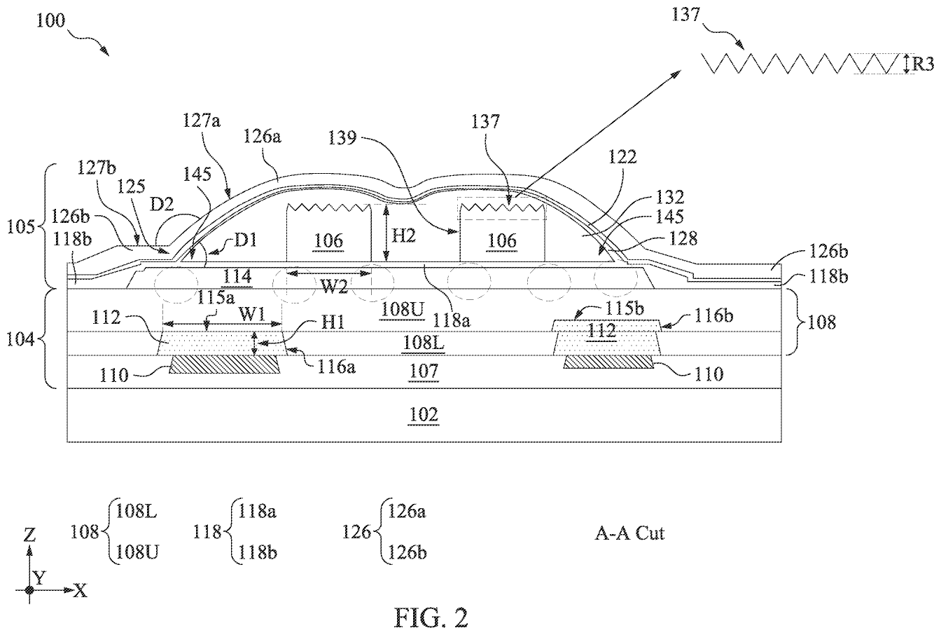

Referring now to FIG. 2, illustrated is a cross-sectional view of a portion of the semiconductor device 100 along the A-A line in FIG. 1, in accordance with some embodiments. In some embodiments, the interconnection structure 104 includes a multi-layer interconnect (MLI) structure 107 and a passivation structure 108 over the MLI structure 107. By way of example, the MLI structure 107, the passivation structure 108, as well as other layers, features, components, or devices formed over the MLI structure 107, which may be formed as part of a back end of line (BEOL) process.

The MLI structure 107 may include multiple patterned dielectric layers and conductive layers that provide interconnections (e.g., wiring) between the various microelectronic components formed within the substrate 102 and upper conductive features in the passivation structure 108. As noted, the MLI structure 107 may include a plurality of conductive features and a plurality of dielectric layers used to provide isolation between the conductive features. In some embodiments, the dielectric layers of the MLI structure 107 may include silicon oxide or a silicon oxide containing material where silicon exists in various suitable forms. In some examples, the dielectric layers may include a low-k dielectric layer (e.g., having a dielectric constant less than that of SiO₂ which is about 3.9) such as oxide formed from tetraethylorthosilicate (TEOS), undoped silicate glass (USG), or doped silicon oxide such as borophosphosilicate glass (BPSG), fluorosilicate glass (FSG), phosphosilicate glass (PSG), boron doped silicon glass (BSG), and/or other suitable low-k dielectric material.

In some embodiments, the conductive features of the MLI structure 107 may include contacts, vias, or metal lines (e.g., a top metal line 110) to provide horizontal and vertical interconnections. In some cases, the metal lines include copper (Cu), aluminum (Al), an aluminum copper (AlCu) alloy, ruthenium (Ru), cobalt (Co), or other appropriate metal layer. In some examples, the contacts and/or vias may include Cu, Al, an AlCu alloy, Ru, Co, tungsten (W), or other appropriate metal layer. In some embodiments, the metal lines, the contacts, and/or vias include a barrier layer and a bulk metal layer over the barrier layer.

The top metal lines (e.g., the top metal line 110) are sometimes referred to as top metal (TM) contacts because they represent a top metal layer of the MLI structure 107, previously discussed. By way of example, formation of the top metal lines (e.g., the top metal line 110) includes multiple processes. The top metal line 110 may be formed by patterning the dielectric layers of the MLI structure 107 to form a trench, depositing a barrier layer in the trench, and depositing a metal fill layer over the barrier layer. In various examples, the dielectric layers may be patterned using a suitable combination of photolithography processes (e.g., such as photoresist deposition, exposure, and development) to form an etch mask, and an etching process may be performed using the etch mask to form the trench. In some cases, a hard mask layer (e.g., such as a nitride-containing layer) may be used as part of the patterning process of the dielectric layers. It will be understood that other top metal lines may likewise be formed in other trenches provided by the patterning of the dielectric layers. In some embodiments, the barrier layer is formed in each of the trenches provided by the patterning of the dielectric layers, followed by the deposition of a metal fill layer over the barrier layer. In some embodiments, the barrier layer includes titanium nitride, tantalum, tantalum nitride, or combinations thereof. In some embodiments, the metal fill layer includes a metal or metal alloy such as copper, cobalt, nickel, aluminum, tungsten, titanium, or combinations thereof. In some embodiments, the metal fill layer is formed by deposition or plating, followed by a chemical mechanical planarization (CMP) process.

In some embodiments, the passivation structure 108 is formed over the MLI structure 107 and over the top metal line 110 as shown in FIG. 2. In some embodiments, the passivation structure 108 includes multiple passivation layers. The multiple passivation layers may include a protection layer including a nitrogen-containing material and/or a carbon-containing material. For example, the protection layer may include SiCN, SiOC, SiC, SiOCN, SiN, or combinations thereof. In various examples, the protection layer may be deposited by CVD, ALD, PVD, or combinations thereof. In some embodiments, the protection layer may protect the top metal lines from being oxidized.

The multiple passivation layers may further include a plasma-enhanced oxide (PEOX) layer formed over the protection layer. In some embodiments, the PEOX layer may include silicon oxide or a silicon oxide containing material. In some cases, the PEOX layer may include undoped silicate glass (USG). The PEOX layer may be deposited by PECVD, HDP-CVD, SACVD, ALD, PVD, or a combination thereof.

In some embodiments, the multiple passivation layers include an ESL. The ESL may be made of or include tantalum oxide, zirconium oxide, tantalum nitride, titanium, one or more other suitable materials, or a combination thereof.

In some embodiments, the passivation structure 108 further includes a polymer layer. The polymer layer may be formed over the multiple passivation layers. In some embodiment, the polymer layer is a topmost layer of the passivation structure 108. In some embodiments, the polymer layer includes epoxy, polyimide (PI), benzocyclobutene (BCB), polybenzoxazole (PBO), or a combination thereof. In some embodiments, the polymer layer includes PI and is referred to as a PI layer. The polymer layer may be deposited over the MLI structure 107 using a suitable deposition technique, such as spin-coating or a vapor-deposition process (VDP).

In some embodiments, the passivation structure 108 includes a conductive pad 112 over the top metal line 110. In some embodiments, the conductive pad 112 includes greater than 97% of Cu (111). In some embodiments, a top surface of the conductive pad 112 includes greater than 97% of Cu (111). In some embodiments, the conductive pad 112 includes less than 3% of a metal or a metal alloy other than Cu (111), such as Cu (110), cobalt, nickel, aluminum, tungsten, titanium. In some embodiments, the top surface of the conductive pad 112 includes less than 3% of a metal or a metal alloy other than Cu (111). Cu (111) is a type of crystalline Cu with specific crystallographic orientations. Cu (111) is more compact and has a relatively low energy surface and lower thermal expansion along three lattice directions as compared to other Cu materials, such as Cu (100) and Cu (110). For the purpose of description in this disclosure, a material having greater than 97% of Cu (111) is also referred to as a “compact copper (Cu) material”. In some embodiments, the conductive pad 112 includes the compact Cu material. In some embodiments, the compact Cu material includes a nano-twinned Cu material, such as a nano-twinned Cu (111) material. The nano-twinned Cu material has an atomic arrangement where crystal lattices on each edge of boundaries are symmetrical across the respective boundaries. Some benefits of the compact Cu material include greater conductance and smaller modulus than other Cu materials. Thus, by including the compact Cu material, the conductive pad 112 may have a reduced resistance and an increased capability to sustain stress, such as a chip package interaction (CPI) stress. Capability to sustain stress herein refers to capability of bearing or tolerating any existing stress. The conductive pad 112 may have any suitable shape. The conductive pad 112 may have a height H1 of about 1 μm to about 7 μm along the Z direction. If H1 is too small, the conductive pad 112 may be too thin to protect the structures therebelow, and resistance of the conductive pad 112 may be too large, causing unnecessary energy waste during operation of the semiconductor device 100. If H1 is too large, capability of the conductive pad 112 to sustain stress may be too small, and it may unnecessarily increase the material of the conductive pad 112 and the costs associated therewith. In some embodiments, a ratio of a width W1 of the conductive pad 112 along the X direction to H1 is about 0.5 to about 15. If the ratio is too small, capability of the conductive pad 112 to sustain stress may be too small. If the ratio is too large, it may unnecessarily increase the footprint of the conductive pad 112 and the costs associated therewith, and/or the conductive pad 112 may be too thin to protect the structures therebelow.

The conductive pad 112 may be formed using any suitable methods. In some examples, after lower layer(s) 108L of the passivation structure 108 is formed over the MLI structure 107 and the top metal line 110, an opening penetrating the lower layer(s) 108L is formed to expose a top surface of the top metal line 110. In some embodiments, the opening may be formed using an etching process (e.g., such as a dry etching process, a wet etching process, or a combination thereof). In various embodiments, sidewalls of the opening may expose sidewalls of the lower layer(s) 108L through which the opening penetrates. In some embodiments, the conductive pad 112 is formed in and over the opening. In some embodiments, to form the conductive pad 112, a compact Cu layer including the compact Cu material is first conformally deposited over the lower layer(s) and into the opening using a suitable deposition technique, such as ALD, PVD, or CVD. In the depicted embodiment, a CMP process may be performed to planarize a top surface 115a of the conductive pad 112 and a top surface of the lower layer(s) 108L. In these embodiments, the top surface 115a and sidewalls 116a have smooth surfaces. In other embodiments, the deposited compact Cu layer is patterned to form the conductive pad 112. In some embodiments, the compact Cu layer is patterned in a one-stage or multiple-stage etch process. In some embodiments, the conductive pad 112 includes an upper portion over the lower layer(s) 108L and a lower portion inside the opening. In some embodiments, the top surface of the conductive pad 112 (e.g., a top surface 115b) is not planarized and has a textured surface, having a surface roughness height R1 of about 10 nm to about 90 nm. A surface roughness height may also be referred to as a peak-to-trough height, which is a distance between a peak and a trough of a surface (e.g., the top surface 115b of the conductive pad 112) perpendicular to the surface (e.g., along the Z direction). In some embodiments, sidewalls of the conductive pad 112 (e.g., sidewalls 116b of the upper portion of the conductive pad 112) has a textured surface, having a surface roughness height R2 of about 10 nm to about 90 nm. In some embodiments, the sidewalls of the conductive pad 112 include greater than 97% of Cu (111) and less than 3% of a metal or a metal alloy other than Cu (111). After forming the conductive pad 112, upper layer(s) 108U of the passivation structure 108 are formed over the conductive pad 112 and the lower layer(s) 108L of the passivation structure 108.

In some embodiments, the conductive pad 112, as well as other similar contact features of the passivation structure 108, are part of a redistribution layer (RDL) that includes various metal lines used to redistribute bonding pads to different locations, such as from peripheral locations to being uniformly distributed on a chip surface. In various examples, the RDL couples the multi-layer interconnect (MLI) structure 107 to the bonding pads, for connection to external circuitry. Further, upper contact features (e.g., contact features in the passivation structure 108, such as the conductive pad 112) provide electrical contact to lower contact features (e.g., contact features in the MLI structure 107, such as the top metal line 110).

In some embodiments, the semiconductor device 100 includes an inductive structure 105 over the passivation structure 108. In some embodiments, the inductive structure 105 includes various components, such as a magnetic element 114, one or more conductors 106, an isolation element 118, a dielectric filler 132, an isolation layer 128, a dielectric layer 122, and a magnetic layer 126.

In some embodiments, the inductive structure 105 includes a magnetic element 114 over the passivation structure 108. The magnetic element 114 extends horizontally along a top surface of the passivation structure 108. The magnetic element 114 may include one or more magnetic layers. In some embodiments, lower layer(s) of the one or more magnetic layers are wider than the upper layer(s) of the one or more magnetic layers along the X direction. In other words, widths of the one or more magnetic layers along the X direction gradually decrease from bottom to top. In some embodiments, the magnetic element 114 includes one or more magnetic materials, such as a cobalt alloy (e.g., cobalt-zirconium-tantalum (CoZrTa or CZT), CoZr, and/or the like), a nickel alloy (e.g., nickel-iron (NiFe) and/or the like), another magnetic material, or a combination thereof. In some embodiments, the magnetic element 114 includes cobalt, zirconium, tantalum, iron, nickel, or a combination thereof. In some embodiments, the magnetic element 114 includes CoZrTa (or CZT).

The magnetic element 114 may be formed by any suitable methods, such as deposition and patterning processes (e.g., sequential deposition and patterning processes). The one or more magnetic layers of the magnetic element 114 may be deposited using a PVD process, a CVD process, an ALD process, one or more other applicable processes, or a combination thereof. A patterned mask layer (not depicted) may be formed over the one or more magnetic layers to assist in a subsequent patterning process of the one or more magnetic layers. In some embodiments, the patterned mask layer is a patterned photoresist layer. A photolithography process may be used to form the patterned mask layer with the desired pattern. For example, the top view of the patterned mask layer may have a square shape, a rectangular shape, or another suitable shape. In some embodiments, with the patterned mask layer as an etching mask, an etching process is used to partially remove the one or more magnetic layers. In some embodiments, the etching process is a wet etching process. The etchant used in the wet etching process may include nitric acid, hydrochloric acid, hydrofluoric acid, one or more other suitable etchants, or a combination thereof. For example, a mixture of nitric acid, hydrochloric acid, and hydrofluoric acid is used in the wet etching process. The ESL in the passivation structure 108 may protect the lower structures of the passivation structure 108 from being damaged during the wet etching process for patterning the one or more magnetic layers.

In some embodiments, the inductive structure 105 includes an isolation element 118. The isolation element 118 includes a first portion 118a over the top surface of the magnetic element 114 and a second portion 118b over the top surface of the passivation structure 108. The isolation element 118 may have a step profile at an interconnection of (or at a boundary between) the first portion 118a and the second portion 118b. The isolation element 118 may insulate the one or more conductors 106 from the magnetic element 114. In some embodiments, the isolation element 118 includes one or more insulating and/or dielectric materials, such as silicon mononitride (SiN), silicon dioxide (SiO), PI, BCB, and/or the like. In some embodiments, the isolation element 118 includes PI.

In some embodiments, the inductive structure 105 includes one or more conductors 106 over the first portion 118a of the isolation element 118. In some embodiments, the inductive structure 105 includes two conductors 106. The two conductors 106 may correspond to an input of the inductive structure 105 (e.g., Vin) and an output from the inductive structure 105 (e.g., Vout). In some embodiments, the one or more conductors 106 include conductive traces, conductive wires, and/or other conductive members. In some embodiments, the one or more conductors 106 include greater than 97% of Cu (111). In some embodiments, the one or more conductors 106 include less than 3% of a metal or a metal alloy other than Cu (111), such as Cu (110), cobalt, nickel, aluminum, tungsten, titanium. In some embodiments, a top surface 137 of the one or more conductors 106 includes greater than 97% of Cu (111) and less than 3% of a metal or a metal alloy other than Cu (111). In some embodiments, sidewalls 139 of the one or more conductors 106 include greater than 97% of Cu (111) and less than 3% of a metal or a metal alloy other than Cu (111). In some embodiments, the one or more conductors 106 include the compact Cu material as described above. By using the compact Cu material that has greater conductance and lower modulus, the one or more conductors 106 may have a reduced resistance and an increased capability to sustain stress, such as a CPI stress, and may also reduce some of the stress. In some examples, the stress occurs in the circled portions of the magnetic element 114 as illustrated in FIG. 2. In some examples, the stress occurs in the magnetic layer 126.

The one or more conductors 106 may have a height of H2 of about 5 μm to about 18 μm along the Z direction. The height H2 may be adjusted to meet design parameters (e.g., resistance and modulus of the one or more conductors 106). Having the height H2 in this range may reduce the stress (e.g., the stress in the circled portions of the magnetic element 114 and/or the stress in the magnetic layer 126). If H2 is too small, resistance of the one or more conductors 106 may be too large, which may increase energy waste during operation of the semiconductor device 100. If H2 is too large, the benefit of reducing stress may not exist, and it may unnecessarily increase the material of the one or more conductors 106 and the costs associated therewith. In some embodiments, a ratio of a width W2 of the one or more conductors 106 along the X direction to H2 is about 0.5 to about 2. If the ratio is too small, capability of the one or more conductors 106 to sustain stress may be too small. If the ratio is too large, it may unnecessarily increase the footprint of the one or more conductors 106 and the costs associated therewith.

The top surface 137 of the one or more conductors 106 may have a textured surface, having a surface roughness height R3 of about 50 nm to about 90 nm as depicted in FIG. 2. In some embodiments, the sidewalls 139 of the one or more conductors 106 have a textured surface, having a surface roughness height R4 of about 10 nm to about 90 nm. In some other embodiments, sidewalls 139 of the one or more conductors 106 have a smooth surface (e.g., having a surface roughness height less than about 5 nm). The surface roughness height R3 of the top surface 137 of the one or more conductors 106 may be greater than the surface roughness height R4 of the sidewalls 139, greater than the surface roughness height R1 of the top surface 115b of the conductive pad 112, and greater than the surface roughness height R2 of the sidewalls 116b of the conductive pad 112. Having the surface roughness heights of the top surface 137 and/or sidewalls 139 may reduce delamination defects of the semiconductor device 100 (e.g., in the magnetic layer 126) and other defects (e.g., cracks in the dielectric filler 132), and/or reduce the stress. If the surface roughness height R3 of the top surface 137 is too small, the benefits of reducing delamination defects and other defects and/or reducing the stress may not exist. If the surface roughness height R3 of the top surface 137 is too large, it may increase defects (e.g., cracks) to the dielectric filler 132.

In some embodiments, the inductive structure 105 includes the dielectric filler 132 over the one or more conductors 106. The dielectric filler 132 fills space between the adjacent one or more conductors 106. In some embodiments, the dielectric filler 132 is disposed on top surfaces and sidewalls of the one or more conductors 106, such that the one or more conductors 106 are embedded in the dielectric filler 132. In the cross-sectional view in FIG. 2, an outline of top surfaces of the dielectric filler 132 has a shape of a hill, such that a top surface of a middle portion of the dielectric filler 132 (e.g., the portion above the one or more conductors 106) is above a top surface of an outer portion of the dielectric filler 132. In some embodiments, the dielectric filler 132 has two wings (or edges) 145 in the outer portions. The two wings 145 are above the first portion 118a of the isolation element 118. The dielectric filler 132 may insulate the one or more conductors 106 from the magnetic layer 126. In some embodiments, the dielectric filler 132 includes one or more insulating and/or dielectric materials, such as silicon mononitride (SiN), silicon dioxide (SiO), a polymer (e.g., epoxy, PI, BCB, PBO), and/or the like. In some embodiments, the dielectric filler 132 includes PI. In some embodiments, the dielectric filler 132 includes a same material as the isolation element 118.

In some embodiments, the inductive structure 105 includes the isolation layer 128 over the dielectric filler 132. The isolation layer 128 may merge with the first portion 118a of the isolation element 118 exterior to the wings 145 of the dielectric filler 132 and have a thickness less than the first portion 118a. The isolation layer 128 may be composed of a similar material as the dielectric filler 132 and the isolation element 118.

In some embodiments, the inductive structure 105 includes the dielectric layer 122 over the dielectric filler 132 and the one or more conductors 106. In some embodiments, the dielectric layer 122 is over top surfaces of the isolation layer 128 and the isolation element 118. The dielectric layer 122 includes a stepped profile exterior to the wings 145 of the dielectric filler 132. An angle D1 between a bottom surface of the dielectric layer 122 and a top surface of the magnetic element 114 is about 20 to about 40 degrees. If D1 is too small, it may unnecessarily increase the footprint of the outer portion of the dielectric filler 132 and the costs associated therewith. If D1 is too large, stress (e.g., the stress of the magnetic element 114 below the wings 145) may be too large. The dielectric layer 122 may include any suitable dielectric materials. In some embodiments, the dielectric layer 122 includes a nitride component, such as silicon nitride (SiN, SiN₄). In some embodiments, the dielectric layer 122 includes SiN₄.

In some embodiments, the inductive structure 105 includes the magnetic layer 126 over a top surface of the dielectric layer 122. The magnetic layer 126 may have uneven thicknesses in different portions. In the depicted embodiment, the magnetic layer 126 includes a first portion 126a over the dielectric filler 132 and a second portion 126b over the second portion 118b and a part of the first portion 118a of the isolation element 118. In some embodiments, the magnetic layer 126 includes a stepped profile at the joint (or boundary) 125 of the first portion 126a and the second portion 126b. In some embodiments, an angle D2 is formed between a top surface 127a of the first portion 126a and a top surface 127b of the second portion 126b at the joint 125. In some embodiments, D2 is about 120 to about 180 degrees. In the cases where D2 is 180 degrees, the top surface 127a of the first portion 126a and the top surface 127b of the second portion 126b at the joint 125 are substantially level (co-planar) with each other. If D2 is too small, delamination defects may occur (e.g., at the joint 125 of the magnetic layer 126). If D2 is too large, it may unnecessarily increase the material of the magnetic layer 126 and the costs associated therewith. In the depicted embodiment, the magnetic layer 126 is separated from the magnetic element 114. In some embodiments, although not depicted in FIG. 2, the magnetic layer 126 is in contact with the magnetic element 114. In such embodiments, the magnetic layer 126 and the magnetic element 114 enclose the one or more conductors 106 and the dielectric filler 132.

In some embodiments, the magnetic layer 126 includes one or more magnetic materials, such as a cobalt alloy (e.g., cobalt-zirconium-tantalum (CoZrTa or CZT), CoZr, and/or the like), a nickel alloy (e.g., nickel-iron (NiFe) and/or the like), another magnetic material, or a combination thereof. In some embodiments, the magnetic layer 126 includes cobalt, zirconium, tantalum, iron, nickel, or a combination thereof. In some embodiments, the magnetic layer 126 includes CoZrTa.

The semiconductor device 100 disclosed herein may be used in any suitable packages, such as a wafer level chip scale package (WLCSP), a flip-chip chip scale package (FCCSP), and a multi-chip module (MCM).

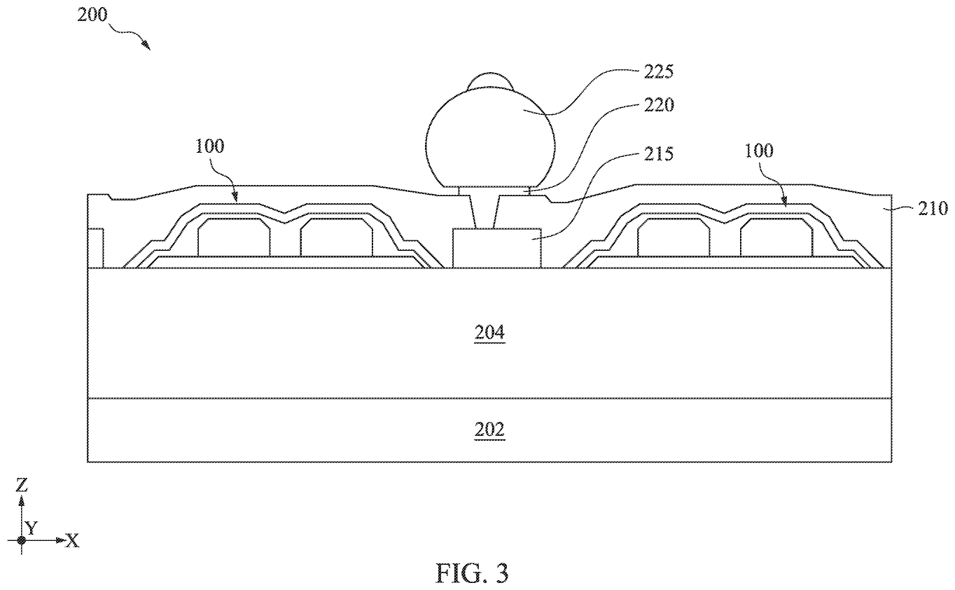

FIG. 3 depicts a cross-sectional view of a portion of a package 200 including the semiconductor device 100, according to some embodiments disclosed herein. The package 200 may be a WLCSP. In some embodiments, the package 200 includes a substrate 202 similar to the substrate 102 described above, an interconnection structure 204 similar to the interconnection structure 104 described above, and the semiconductor device 100. The package 200 may include more than one semiconductor device 100. In some embodiments, the package 200 includes a first conductive feature 215 over the interconnection structure 204 and a second conductive feature 220 over the first conductive feature 215, and a bump 225 over the second conductive feature 220. The first conductive feature 215, the second conductive feature 220, and the bump 225 electrically couple the package 200 with external circuits. In some embodiments, the bump 225 is a solder bump, a Cu bump or a metal bump including Ni or Au. The first conductive feature 215 and the second conductive feature 220 may include various conductive features, such as an under bump metallization (UBM) layer, a via, a metal layer, and may include any suitable metals, such as titanium (Ti), tantalum (Ta), titanium nitride (TiN), tantalum nitride (TaN), copper (Cu), copper alloys, nickel (Ni), tin (Sn), gold (Au), or combinations thereof. In some embodiments, the package 200 includes a protective layer 210 over the semiconductor device 100, the interconnection structure 204, the first conductive feature 215, and the second conductive feature 220. The protective layer 210 may include a polymer, such as an epoxy, PI, BCB, PBO, and the like, although other relatively soft, organic, dielectric materials may also be used. In some embodiments, the protective layer 210 is formed of a non-organic material selected from un-doped silicate glass (USG), silicon nitride, silicon oxynitride, silicon oxide, and combinations thereof.

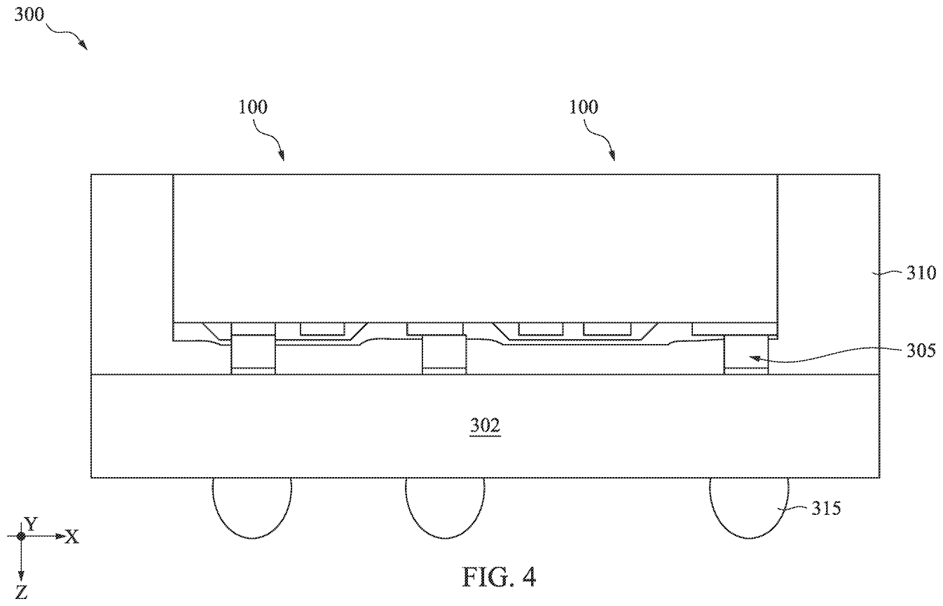

FIG. 4 depicts a cross-sectional view of a portion of a package 300 including the semiconductor device 100, according to some embodiments disclosed herein. The package 300 may be a FCCSP. In some embodiments, the package 300 includes a substrate 302 similar to the substrate 102 described above. In some embodiments, the package 300 includes one or more metal ball structures 315 below the substrate 302 for wiring to other circuits. The semiconductor device 100 of the package 300 is flipped to an upside-down position and is disposed over the substrate 302 as shown in FIG. 4. The semiconductor device 100 may be electrically coupled to the substrate 302 by one or more conductive features 305 below the semiconductor device 100. In some embodiments, the package 300 includes a molded underfill (MUF) 310 over the substrate 302 and filling space between the semiconductor device 100, the one or more conductive features 305, and the substrate 302. In other words, the semiconductor device 100 and the one or more conductive features 305 may be embedded in the MUF 310. In some embodiments, the MUF 310 has fillers. The MUF 310 may be used for protection and insulation purposes. The MUF 310 supports the package 300 and prevents cracking of joints between the semiconductor device 100, the one or more conductive features 305, and the substrate 302. Further, the MUF 310 could also prevent the bending (deformation) of structures on the substrate 302 due to mismatch of coefficients of thermal expansion (CTE) of materials on the substrate 302 after thermal cycling. In some embodiments, the MUF 310 is made of epoxy resin (amine type, phenol type, anhydrates types, etc.), silicon fillers, curing agents, additives and/or hardener materials.

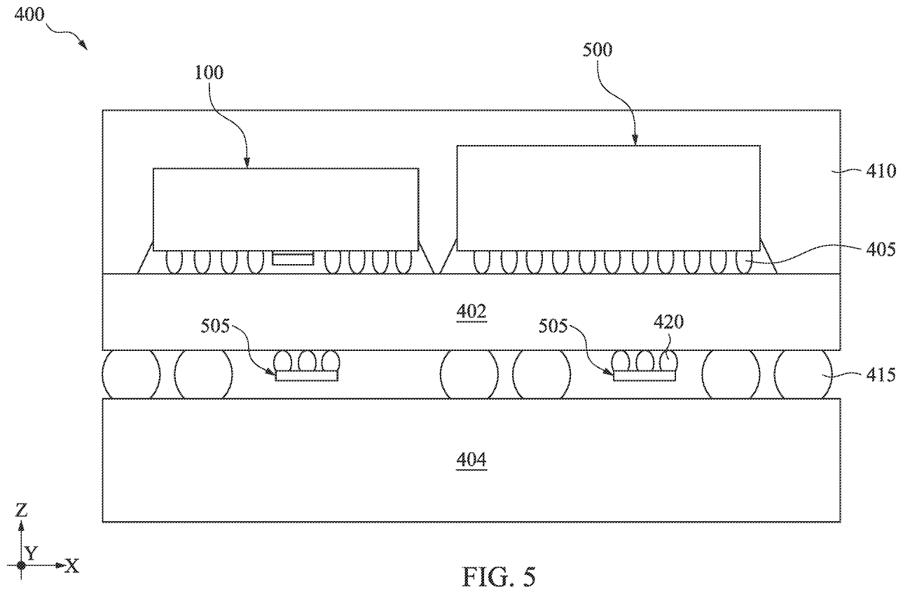

FIG. 5 depicts a cross-sectional view of a portion of a package 400 including the semiconductor device 100, according to some embodiments disclosed herein. The package 400 may be an MCM. In some embodiments, the package 400 includes a substrate 402, a semiconductor device 100 as disclosed herein, and another device 500. The substrate 402 is similar to the substrate 102 described above. The device 500 may be any suitable device, such as a logic device, memory device, power management device, radio frequency (RF) device, or other suitable device. The semiconductor device 100 and the device 500 are disposed over the substrate 402 and are connected to the substrate 402 by one or more conductive features 405. In some embodiments, the package 400 includes a MUF 410 over the substrate 402 and filling space between the semiconductor device 100, the device 500, one or more conductive features 405, and the substrate 402. The MUF 410 is similar to the MUF 310 described above. In some embodiments, the package 400 includes one or more devices 505 below the substrate 402 and connected to the substrate 402 by conductive features 420. In some embodiments, the one or more devices 505 include an integrated passive device (IPD). The package 400 may also include a housing substrate 404 below the substrate 402 and connected to the substrate 402 by metal ball structures 415, which are similar to the metal ball structures 315 described above. The housing substrate 404 may include a printed circuit board (PCB) or the like.

The various embodiments described herein thus offer several advantages over the existing art. It will be understood that not all advantages have been necessarily discussed herein, no particular advantage is required for all embodiments, and other embodiments may offer different advantages. As one example, by having the compact Cu material in the conductive pad and/or the conductors, the semiconductor devices disclosed herein have improved capabilities to sustain and/or mitigate stress and enhance electrical performance, such as by increasing conductance and reducing wasted energy. In some examples, the semiconductor devices reduce and/or eliminate delamination defects by having optimal prescribed dimensions (e.g., heights of the conductive pad and the conductors, angles D1 and D2) and surface roughness heights of the conductive pad and/or the conductors. As a result, stress and any potential cracks in the semiconductor devices resulting therefrom, can be reduced and/or avoided. Additional benefits and/or other advantages will become apparent to those skilled in the art having benefit of the present disclosure.

In one example aspect, the present disclosure is directed to a semiconductor device that includes an interconnection structure over a substrate, a first magnetic layer over the interconnection structure, one or more conductive features over the first magnetic layer, a dielectric layer over the first magnetic layer and the one or more conductive features, and a second magnetic layer over the dielectric layer. The one or more conductive features include a textured top surface.

In some embodiments, the one or more conductive features includes over 97% of Cu (111). In some embodiments, a taper angle between the dielectric layer and the first magnetic layer is about 20 to about 40 degrees. In some embodiments, the textured top surface has a surface roughness height of about 50 nm to about 90 nm. In some embodiments, the dielectric layer is a first dielectric layer, the semiconductor device further comprises a second dielectric layer between the one or more conductive features and the first dielectric layer, the first magnetic layer extends beyond an edge of the second dielectric layer, and top surfaces of the second magnetic layer form a step angle of about 120 to about 180 degrees above the edge of the second dielectric layer. In some embodiments, the one or more conductive features have a height of about 5 μm to about 18 μm. In some embodiments, the interconnection structure includes a top metal line, the semiconductor device further comprises a conductive pad over the top metal line, the conductive pad includes over 97% of Cu (111), and the conductive pad has a height of about 1 μm to about 7 μm. In some embodiments, the first magnetic layer and the second magnetic layer include a cobalt alloy, a nickel alloy, or a combination thereof. In some embodiments, the dielectric layer includes SiN₄, SiN, or a combination thereof.

In another example aspect, the present disclosure is directed to a semiconductor device that includes a top metal line over a substrate, a conductive pad over the top metal line, two conductive features over the conductive pad, a dielectric layer over the two conductive features, and a magnetic layer over the dielectric layer. Top surfaces of the conductive pad and the two conductive features each include a compact copper (Cu) material.

In some embodiments, a top surface of the two conductive features includes a textured Cu (111) surface, the textured Cu (111) surface has a surface roughness height R3 of about 50 nm to about 90 nm. In some embodiments, sidewalls of the two conductive features have a surface roughness height R4 less than R3. In some embodiments, the compact Cu material includes over 97% of Cu (111). In some embodiments, the magnetic layer is a first magnetic layer, and the semiconductor device further includes a second magnetic layer over the conductive pad and below the two conductive features. In some embodiments, the dielectric layer is a first dielectric layer, and the semiconductor device further includes a second dielectric layer extending horizontally and below the two conductive features, and a third dielectric layer disposed below the first dielectric layer and above the second dielectric layer and the two conductive features. The third dielectric layer has an edge directly above the second dielectric layer, the magnetic layer includes two top surfaces forming a step angle above the edge, and the step angle is about 120 to about 180 degrees. In some embodiments, the magnetic layer is a first magnetic layer, and the semiconductor device further includes a second magnetic layer disposed below the second dielectric layer and extends horizontally. In some embodiments, the magnetic layer includes cobalt zirconium tantalum (CZT), and the dielectric layer includes SiN₄.

In yet another example aspect, the present disclosure is directed to a semiconductor device that includes two conductive features over a substrate and embedded in a first dielectric layer, a second dielectric layer over the two conductive features and the first dielectric layer, and a magnetic layer over the second dielectric layer. The two conductive features include a copper (Cu) (111) surface having a surface roughness height of about 50 nm to about 90 nm.

In some embodiments, the two conductive features include over 97% of Cu (111). In some embodiments, the magnetic layer is a first magnetic layer, the semiconductor device further includes a second magnetic layer disposed below the two conductive features, an angle between the second dielectric layer and the second magnetic layer is about 20 to about 40 degrees.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
an interconnection structure over a substrate;
a first magnetic layer over the interconnection structure;
one or more conductive features over the first magnetic layer;
a dielectric layer over the first magnetic layer and the one or more conductive features; and
a second magnetic layer over the dielectric layer,
wherein the one or more conductive features include a textured top surface.

2. The semiconductor device of claim 1, wherein the one or more conductive features includes over 97% of Cu (111).

3. The semiconductor device of claim 1, wherein a taper angle between the dielectric layer and the first magnetic layer is about 20 to about 40 degrees.

4. The semiconductor device of claim 1, wherein the textured top surface has a surface roughness height of about 50 nm to about 90 nm.

5. The semiconductor device of claim 1, wherein the dielectric layer is a first dielectric layer,
wherein the semiconductor device further comprises a second dielectric layer between the one or more conductive features and the first dielectric layer,
wherein the first magnetic layer extends beyond an edge of the second dielectric layer, and
wherein top surfaces of the second magnetic layer form a step angle of about 120 to about 180 degrees above the edge of the second dielectric layer.

6. The semiconductor device of claim 1, wherein the one or more conductive features have a height of about 5 μm to about 18 μm.

7. The semiconductor device of claim 1, wherein the interconnection structure includes a top metal line,
wherein the semiconductor device further comprises a conductive pad over the top metal line,
wherein the conductive pad includes over 97% of Cu (111), and
wherein the conductive pad has a height of about 1 μm to about 7 μm.

8. The semiconductor device of claim 1, wherein the first magnetic layer and the second magnetic layer include a cobalt alloy, a nickel alloy, or a combination thereof.

9. The semiconductor device of claim 1, wherein the dielectric layer includes SiN₄, SiN, or a combination thereof.

10. A semiconductor device, comprising:
a top metal line over a substrate;
a conductive pad over the top metal line;
two conductive features over the conductive pad;
a dielectric layer over the two conductive features; and
a magnetic layer over the dielectric layer,
wherein top surfaces of the conductive pad and the two conductive features each include a compact copper (Cu) material.

11. The semiconductor device of claim 10, wherein a top surface of the two conductive features includes a textured Cu (111) surface,
wherein the textured Cu (111) surface has a surface roughness height R3 of about 50 nm to about 90 nm.

12. The semiconductor device of claim 11, wherein sidewalls of the two conductive features have a surface roughness height R4 less than R3.

13. The semiconductor device of claim 10, wherein the compact Cu material includes over 97% of Cu (111).

14. The semiconductor device of claim 10, wherein the magnetic layer is a first magnetic layer, the semiconductor device further comprising a second magnetic layer over the conductive pad and below the two conductive features.

15. The semiconductor device of claim 10, wherein the dielectric layer is a first dielectric layer, wherein the semiconductor device further comprises:
a second dielectric layer extending horizontally and below the two conductive features; and
a third dielectric layer disposed below the first dielectric layer and above the second dielectric layer and the two conductive features, wherein the third dielectric layer has an edge directly above the second dielectric layer,
wherein the magnetic layer includes two top surfaces forming a step angle above the edge, and
wherein the step angle is about 120 to about 180 degrees.

16. The semiconductor device of claim 15, wherein the magnetic layer is a first magnetic layer, the semiconductor device further comprising a second magnetic layer disposed below the second dielectric layer and extends horizontally.

17. The semiconductor device of claim 10, wherein the magnetic layer includes cobalt zirconium tantalum (CZT), and wherein the dielectric layer includes SiN₄.

18. A semiconductor device, comprising:
two conductive features over a substrate and embedded in a first dielectric layer;
a second dielectric layer over the two conductive features and the first dielectric layer; and
a magnetic layer over the second dielectric layer,
wherein the two conductive features include a copper (Cu) (111) surface having a surface roughness height of about 50 nm to about 90 nm.

19. The semiconductor device of claim 18, wherein the two conductive features include over 97% of Cu (111).

20. The semiconductor device of claim 18, wherein the magnetic layer is a first magnetic layer,
wherein the semiconductor device further comprises a second magnetic layer disposed below the two conductive features,
wherein an angle between the second dielectric layer and the second magnetic layer is about 20 to about 40 degrees.
